(19) United States
(12) Patent Application Publication
(10) Pub. No.: US 2024/0332126 A1
(43) Pub. Date: Oct. 3, 2024

(54) THERMAL GROUNDING IN BACKSIDE POWER SCHEMES USING CARRIER WAFERS

(71) Applicant: Intel Corporation, Santa Clara, CA (US)

(72) Inventors: Andy Wei, Yamhill, OR (US); Po-Yao Ke, Kaohsiung City (TW); Kai-Chiang Wu, Hsinchu City (TW); Han-wen Lin, Zhubei City (TW); Klaus Max Schruefer, Baldham (DE); Dean Huang, Hsinchu City (TW); Hsin-Hua Wang, San Jose, CA (US)

(73) Assignee: Intel Corporation, Santa Clara, CA (US)

(21) Appl. No.: 18/129,654

(22) Filed: Mar. 31, 2023

(51) Int. Cl. H01L 23/373; H01L 23/367

(52) U.S. Cl. CPC H01L 23/3737; H01L 23/3677; H01L 23/3735; H01L 23/481

(57) ABSTRACT

Thermal dissipation and grounding of integrated circuit (IC) devices with backside power delivery networks are discussed. An IC device layer between frontside and backside interconnect sections, composed mostly of an insulating material, is coupled to a crystalline heat spreader or a metal thermal ground layer by an array of thermal pillars extending through the insulating material. The crystalline heat spreader layer may include one or more thermal sensors, such as thermal sensing diodes, also coupled to the IC device layer by one or more thermal pillars. The IC device layer and crystalline layers are coupled by a hybrid bond, which forms the thermal pillars through a continuous section of the insulating material.

### BACKGROUND

Backside power delivery is an emerging technology that allows for optimized signal transmission by eliminating the need for frontside power routing. However, as advances are made, new problems are encountered. Innovative structures and techniques are needed to improve thermal dissipation and sensing in integrated circuit devices with backside power delivery.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A, 1B, 1C, 1D, and 1E illustrate cross-sectional profile and plan views of integrated circuit (IC) devices with backside power delivery and a thermal ground layer, in accordance with some embodiments;

FIGS. 2A and 2B illustrate cross-sectional profile and plan views of an IC device with a thermal ground layer coupled to device layer by an array of thermal pillars, in accordance with some embodiments;

FIGS. 3A and 3B illustrate cross-sectional profile views of an IC device with a heat spreader die, including a thermal ground layer coupled to a device layer by an array of thermal pillars, in accordance with some embodiments;

FIGS. 4A and 4B illustrate cross-sectional profile and plan views of an IC device with temperature sensors over a thermal ground layer and a core in a device layer, in accordance with some embodiments;

FIGS. 5A and 5B illustrate cross-sectional profile views of an IC device with a heat spreader die, including a temperature sensor over a thermal ground layer, coupled to a device layer by an array of thermal pillars, in accordance with some embodiments;

FIGS. 6A and 6B illustrate cross-sectional plan views of an IC device, including a thermal ground layer over cores in an IC die, in accordance with some embodiments;

FIGS. 7A and 7B illustrate cross-sectional profile views of IC devices, including with multiple dies stacked over a package substrate, in accordance with some embodiments;

FIGS. 8A and 8B are flow charts of methods for forming an array of thermal pillars and coupling an IC device layer to a thermal ground layer with the array, in accordance with some embodiments;

FIG. 9 illustrates a diagram of an example data server machine employing an IC device having an array of thermal pillars contacting, and coupling between, a device layer and a heat spreader layer, in accordance with some embodiments; and

FIG. 10 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Materials, structures, and techniques are disclosed to improve the performance of integrated circuit (IC) devices with backside delivery networks. When combined, frontside and backside interconnect sections composed mostly of dielectric material (with metallization structure within) insulate an IC device layer between the dielectric materials above and below. This insulation interferes with thermal conduction, increasing hotspot temperature and interfering with sensing of hotspots in the device layer. This endangers the reliability of the device. A thermal ground layer, for example, of copper, between the upper (e.g., frontside, back-end-of-line (BEOL)) interconnect section and package lid may be thermally coupled to the IC device layer. This thermal ground layer may be in contact with a crystalline heat spreader layer above the thermal ground layer, and may be thoroughly connected to the IC device layer by a large array thermal via pillars. Additionally, thermal sensing diodes can be placed directly over thermal hotspots, e.g., as modeled by thermal analysis, for highest accuracy thermal sensing. Thermal dissipation and thermal sensing are critical to high-performance compute products with high-power dissipation. Without these, devices are limited in speed since power dissipation is directly proportional to frequency, and without proper thermal dissipation and thermal sensing, product reliability is not predictable or easily ensured.

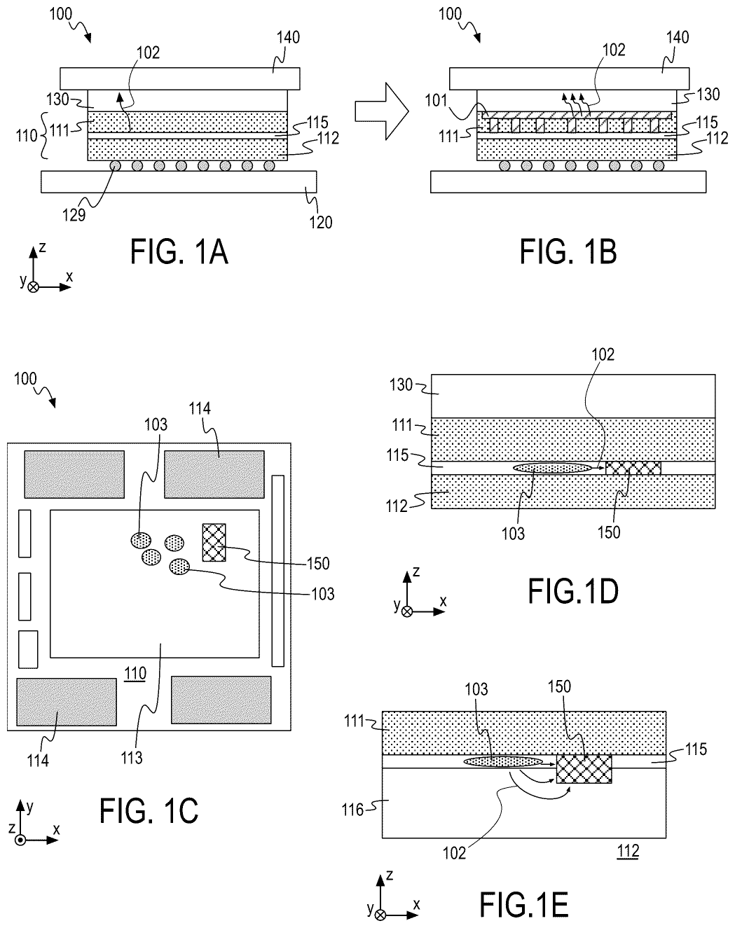

FIGS. 1A, 1B, 1C, 1D, and 1E illustrate cross-sectional profile and plan views of an IC device 100 with backside power delivery and a thermal ground layer 101, in accordance with some embodiments. FIG. 1A illustrates an integrated circuit (IC) device 100 with backside power delivery to a device layer 115 in an IC die 110. IC device 100 has a potential insulation problem with interconnect sections 111, 112 above and below device layer 115, where electrical power is consumed and converted to thermal energy or heat 102. Device layer 115 is electrically connected to metallization structures routed through interconnect sections 111, 112. Both interconnect sections 111, 112 may be mostly thermally and electrically insulating materials, for example, dielectrics built up on a substrate at a back-end-of-line (BEOL) process. Backside power delivery to device layer 115 is by a metallization structure through lower interconnect section 112. Interconnect section 112 may have been built up on a backside of device layer 115 at a far BEOL (FBEOL) process after upper interconnect section 111 was built up on a frontside of device layer 115 at a BEOL process. The metallization structures may couple the power from a package substrate 120 through micro bumps or solder bumps 129. While a thermally conductive heat spreader die 130 (e.g., for example, of silicon or another crystalline material) may conduct heat 102 well, e.g., upward to a package lid 140, the backside power scheme sandwiches device layer 115 between insulating interconnect sections 111, 112. Upper interconnect section 111 may inhibit heat dissipation between layer 115 and die 130 and may result in increased hotspot temperatures due to self-heating, increasing the risks of reliability failures. Some dielectrics (e.g., a silicon dioxide) may be ˜50 times more thermally resistant than some semiconductor materials (such as silicon), and ˜150 times more thermally resistant than a conductor material, such as copper.

FIG. 1B shows the same or a similar IC device 100 with dies 110, 130, but with a thermal ground layer 101 thermally coupled to both device layer 115 and heat spreader die 130. Thermal ground layer 101 may improve dissipation of heat 102 from device layer 115 to heat spreader die 130 and/or lid 140, which may also be a heat spreader. Thermal ground layer 101 may be a layer of thermally conducting material (such as copper) in contact with heat spreader die 130 or lid 140. Thermal ground layer 101 is thermally coupled to device layer 115 by intervening metallization (as will be described further).

FIGS. 1C, 1D, and 1E illustrate a problem of poor thermal sensing resolution due to a temperature sensor 150 being confined to device layer 115. Heat 102 conducts poorly between thermal hotspots 103 and sensor 150 as layer 115 may be made mostly of dielectric isolation (e.g., shallow-trench isolation (STI)) and may have issues of low heat conduction similar to those of interconnect sections 111, 112. The plan view of device layer 115 in FIG. 1C shows how, with sensor 150 confined to a same layer, hotspots 103 (e.g., in core region 113 between input/output (I/O) regions 114) will be laterally separated from sensor 150. In FIG. 1D, device layer 115 is a thin layer with dielectric isolation and some metallization and semiconductor material. Heat 102 conduction to sensor 150 is substantially limited to the poor thermal conducting layer 115 between thermal insulating interconnect sections 111, 112. In FIG. 1E, even with a thicker semiconductor substrate 116 (e.g., of silicon) remaining, e.g., thinned less before a buildup of dielectric material in lower interconnect section 112, paths for detecting hotspots 103 are limited. Heat 102 must conduct laterally to sensor 150 through substrate 116 (though through a longer path), as well as the poorly conducting layer 115. The high thermal conductance of the silicon substrate 116 allows moderately good thermal detection capability despite the lateral separation between the thermal hotspot 101 and the thermal sensor 150. However, thermal detection capability improvements are possible.

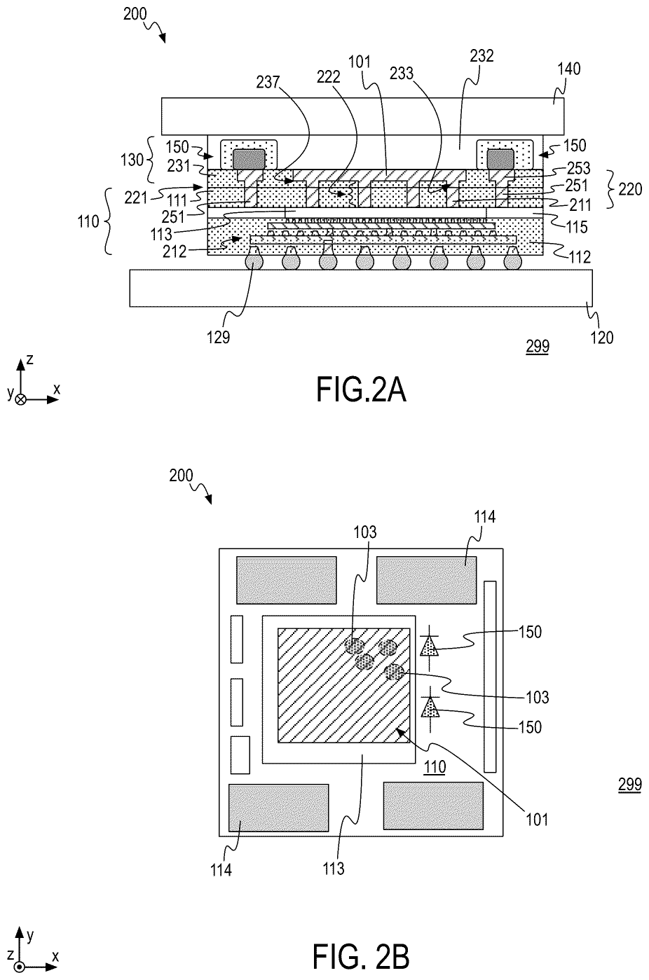

FIGS. 2A and 2B illustrate cross-sectional profile and plan views of IC device 200 with thermal ground layer 101 coupled to device layer 115 by an array of thermal pillars 222, in accordance with some embodiments. The cross-sectional profile view of FIG. 2A shows IC device 200 having two dies 110, 130 coupled together between package substrate 120 and lid 140. IC die 110 includes device layer 115 between two interconnect sections 111, 112, one on a frontside and another on a backside of device layer 115. IC die 110 and heat spreader die 130 are coupled by a hybrid bond at interface 221. An array of thermal pillars 211 in IC die 110 are coupled by direct bonds at interface 221 to an array of thermal pillars 233 in die 130. Each pair of thermal pillars 211, 233, stacked and coupled end to end, together form a thermal pillar 222 with a height equal to the sum of the heights of thermal pillars 211, 233. Thermal ground layer 101 in heat spreader die 130 is coupled to device layer 115 in IC die 110 by the arrays of thermal pillars 222.

IC die 110 may be of any suitable material(s). For example, die 110 may include any suitable semiconductor or other material. Device layer 115 in die 110 may be of the same material as a semiconductor substrate or one or more other materials, e.g., deposited on a semiconductor substrate. Such a substrate may include any semiconductor material that transistors can be formed out of or on, including a crystalline material. In some examples, the substrate may include monocrystalline silicon (Si), germanium (Ge), silicon germanium (SiGe), a III-V alloy material (e.g., gallium arsenide (GaAs)), a silicon carbide (SiC), a sapphire (Al₂O₃), or any combination thereof. In some embodiments, the substrate includes crystalline silicon and subsequent components are also silicon. But, even if device layer 115 was formed from or on a semiconductor or crystalline substrate, such a substrate may not be readily observable. For example, much of any such semiconductor or insulator material may be removed, e.g., from under device layer 115. The height (e.g., in the z direction) of device layer 115 may be limited or defined by a height of any remaining semiconductor or insulator material or by a height of a shallow-trench isolation (STI) formed, e.g., between devices in layer 115. Such an STI may have a height of tens of nanometers. In some embodiments, an STI has a height of 50 nm.

IC die 110 may also include other materials commonly found in semiconductor substrates, such as metals, dielectrics, dopants, etc. Device layer 115 may include transistor structures over a dielectric layer or other materials. Such transistor structures may be throughout layer 115, but may be particularly concentrated in a core 113. As conduction through, and switching of, transistors is where the majority of heat in IC die 110 may be generated, the formation of hotspots may be most likely in (or entirely confined to) core 113.

IC die 110 also includes interconnect sections 111, 112. Interconnect sections 111, 112 are dielectric sections above and below device layer 115 that each include a metallization structure on corresponding sides of device layer 115. The terms “dielectric section” and “interconnect section” may be used to refer to sections 111, 112. Dielectric or interconnect sections may be characterized as including multiple interconnect layers, which may include metallization structure(s) routed through interlayer and intermetal dielectric material. These interconnect layers may be buildup layers on a frontside or backside of device layer 115. Interconnect section 111 is between device layer 115 and heat spreader die 130, and may include buildup layers, e.g., on a frontside of device layer 115 at a back-end-of-line (BEOL) process. Interconnect section 112 is between device layer 115 and substrate 120, and may include buildup layers, e.g., on a backside of device layer 115 at a far BEOL (FBEOL) process. Additional interconnect, e.g., at a middle-of-line (MOL) process may enable contact and other interconnection between devices and large-pitch (e.g., FBEOL) metallization. Interconnect sections 111, 112 are composed mostly of thermally and electrically insulating materials, for example, one or more dielectric materials. An electrically insulating material may be considered a material with a resistivity greater than 10⁶ Ω·m at 20° C. or a conductivity, α, less than 10⁻⁶ S/m at 20° C. Such material in interconnect sections 111, 112, rather than high-permittivity (“high-k”) dielectrics, e.g., strategically located within transistor structures, may mostly be composed of low-permittivity (“low-k”) dielectrics meant to insulate and isolate electrical structures from each other. Such insulating materials may include more air or other low-density materials or spaces. Such insulating materials may include one or more oxides, such as a silicon oxide (e.g., SiO₂, etc.). These materials may be porous for low-k value with voids and be even higher thermal insulators insulator than common oxide-based dielectrics. The dielectric separation of the metals may also be made of pure dielectrics surrounding an “airgap”. Airgaps in the dielectrics would have the absolute lowest thermal conductivity. Other oxides, oxycarbides, oxynitrides, with and without porosity and airgaps, and other materials may be incorporated in one or more of multiple layers within sections 111, 112. Interconnect sections 111, 112 may each have a height or thickness of a few microns or more, e.g., multiple tens of microns. In some embodiments, one or both of interconnect sections 111, 112 have a z-height of 50 μm. In some embodiments, each of interconnect sections 111, 112 are predominantly of an electrically insulating material, and each of interconnect sections 111, 112 have a z-height greater than a z-height of device layer 115 between interconnect sections 111, 112. In some embodiments, each of interconnect sections 111, 112 are predominantly of an electrically insulating material, and each of interconnect sections 111, 112 have a z-height greater than a z-height of a crystalline semiconductor substrate or layer between interconnect sections 111, 112.

Device layer 115 is coupled to a metallization structure 212 within interconnect section 112, and metallization structure 212 couples device layer 115 to substrate 120. Interconnect section 111 may include a metallization structure over device layer 115 with connections, e.g., electrical connections, to device layer 115. Much of the electrical interconnections in interconnect section 111 may interconnect structures within device layer 115. Such electrical connections may be to structures in or on device layer 115, but may also be down to metallization structure 212. Much of metallization structure 212 in interconnect section 112 may span the height of interconnect section 112 to couple to substrate 120. Interconnect section 112 may have a greater z-height than interconnect section 111, as metallization structure 212 may include larger conductors and with larger pitches, e.g., for coupling with package substrate 120. One of sections 111, 112, for example, interconnect section 111, may be built up over device layer 115 on a frontside of a semiconductor substrate, e.g., at a back-end-of-line operation following the manufacture of transistor structures in layer 115. The other of sections 111, 112, for example, interconnect section 112, may be built up over a backside of device layer 115, e.g., at a FBEOL operation following the removal of much of a semiconductor substrate under layer 115. Such a buildup may mostly be of dielectric material with some metallization within the dielectric material, and interconnect sections 111, 112 are mostly insulating dielectric sections on either side of device layer 115. With the bulk of interconnect sections 111, 112 being thermally insulating materials, dissipating relatively large quantities of heat generated in device layer 115, e.g., in core 113, between sections 111, 112 may require additional structures.

Heat spreader die 130 includes thermal ground layer 101 coupled to device layer 115 by thermal pillars 222. In the example of FIG. 2A, thermal ground layer 101 is a planar structure of copper spanning over most of the area of core 113. The array of thermal pillars 222 are in contact with device layer 115 and thermal ground layer 101, terminating at an edge 237 of dielectric section 220, at an interface of dielectric section 220 and thermal ground layer 101. Generally, thermal ground layer 101 is a structure with a high thermal conductance and with very many thermal connections (e.g., hundreds of millions) to many points in device layer 115 by thermal pillars 222. These characteristics make thermal ground layer 101 a thermal analog to an electrical ground plane, e.g., in a multilayer printed circuit board (PCB). The high thermal conductance of thermal ground layer 101 makes layer 101 a thermal reference or common point. Thermal ground layer 101 may include a thermally conductive material, such as a metal (e.g., copper). Such a thermally conductive material not only aids in dissipation of heat upward from device layer 115 to lid 140, but also allows for the quick transfer of heat laterally. For example, thermal ground layer 101 may provide a quick heat transfer path from a hotspot outward to equalize to a common thermal level across thermal ground layer 101 and the area or span of core 113. Advantageously, thermal ground layer 101 is thick enough (e.g., in the z direction) to provide a sufficiently high thermal conductance laterally, but not so thick to inhibit heat transfer vertically. As with voltage levels decreasing from a high at a power supply to a low at an electrical ground or common point (with intermediate voltage levels at various intervening points in an electrical circuit), the thermal reference point of thermal ground layer 101 may also be a relatively low level thermally. (This is relative to device layer 115 at least-heat may still sink or flow from a copper thermal ground layer 101 to a lower-temperature lid 140, which may be an integrated heat spreader.)

Heat spreader die 130 includes a crystalline substrate or layer 232, for example, of silicon, which is in contact with thermal ground layer 101. Heat spreader die 130 also includes a dielectric material 231 over thermal ground layer 101 and crystalline layer 232. Crystalline layer 232 is a layer or substrate of a thermally conductive, crystalline material that may assist in dissipating heat from device layer 115. At least a portion of crystalline layer 232 is directly above thermal ground layer 101 and/or thermal pillars 222. Crystalline layer 232 may be of any suitable material. For example, crystalline layer 232 may be silicon, which may be sufficiently thermally conductive for dissipating heat from device layer 115 upward and outward to lid 140. Other materials may be employed. Silicon may advantageously also be readily available in IC manufacturing settings and relatively inexpensive. Silicon (or another semiconductor material) in crystalline layer 232 may also provide an acceptable substrate for the location of thermal sensors 150. Heat spreader die 130 may also be a carrier or handle die or wafer during manufacture of IC device 200, e.g., with a hybrid bond to a frontside interconnect section of IC die 110, to enable the removal of a substrate on a backside of device layer 115.

Dielectric material 231 in die 130 may be the same or similar to the electrically insulating materials of interconnect sections 111, 112. For example, dielectric material 231 may include a low-k oxide. Dielectric material 231 may isolate electrical components from each other, e.g., thermal pillars 233, 253. Dielectric material 231 may also act as a substrate or structure for forming metallization structures, for example, thermal ground layer 101 and thermal pillars 233, 253. Advantageously, dielectric material 231 may readily form a dielectric bond with an electrically insulating material of interconnect section 111. Dielectric material 231 in die 130 and an electrically insulating material of interconnect section 111 in die 110 are bonded at interface 221, which together form a continuous dielectric section 220. Dielectric section 220 spans between device layer 115 and thermal ground layer 101, as well as between device layer 115 and crystalline layer 232. Dielectric section 220 includes hybrid bond interface 221.

Thermal pillars 211, 233 may be much like metallization in electrical interconnect sections 111, 112, electrical vias composed of one or more metals, such as copper, extending vertically through a dielectric, e.g., material 231 or in interconnect section 111. Thermal pillars 233 in dielectric material 231 and die 130 contact thermal ground layer 101 at upper edge 237 of dielectric material 231 (which is also upper edge 237 of dielectric section 220). Thermal pillars 211 in interconnect section 111 and die 110 contact device layer 115. Thermal pillars 233 in die 130 contact thermal pillars 211 in die 110 at hybrid bond interface 221, where pillars 211, 233 are direct bonded. Together, direct bonded thermal pillars 211, 233 form thermal pillars 222. Hybrid bond interface 221 includes direct bonds between pillars 211, 233 and dielectric bonds between dielectric material 231 and the dielectric material of interconnect section 111.

Thermal pillars 211, 222, 233 may be electrically grounded, for example, through contacts and electrical connections at device layer 115 (and, e.g., through metallization structure 212 to package substrate 120). In this way, thermal pillars 211 may serve as “lightning rods,” e.g., during manufacture of IC die 110, and protect against antenna effects, e.g., plasma-induced damage, such as to gate dielectrics or other structures. Thermal pillars 222 may electrically ground thermal ground layer 101, for example, through contacts and electrical connections at upper edge 237.

Heat spreader die 130 includes thermal sensors 150 in crystalline layer 232. Thermal sensors 150 are coupled, both electrically and thermally, to device layer 115 by thermal pillars 251, 253. Thermal sensors 150 in crystalline layer 232 and coupled by metal thermal pillars 251, 253 may have better resolution (e.g., thermal coupling to hotspots 103) than thermal sensors 150 in device layer 115 and insulated from hotspots 103 by dielectric material. Also, thermal sensors 150 may be vertical (rather than lateral) diodes, which may provide advantages, as described elsewhere herein (e.g., higher and more predictable ideality). Thermal sensors 150 may be situated wherever is convenient or otherwise suitable, for example, adjacent core 113.

Substrate 120 is a planar platform and may include dielectric and metallization structures. Substrate 120 may be a package substrate with a redistribution layer (RDL) or similar, interposer structure, or any other suitable structure for coupling with die 110 and metallization structure 212 of interconnect section 112. For example, substrate 120 may include electrical lines (e.g., conductive traces and vias) through one or more organic and/or inorganic insulators, such as metallization (e.g., copper) in or on a core of glass, fiberglass, resin, etc. Substrate 120 may be another die, e.g., of silicon or other crystalline material. At least one side of substrate 120 includes interconnect interfaces for bonding to one or more IC dies 110. Substrate 120 may be coupled to die 110 by any suitable means, e.g., with solder bumps 129 to interconnect section 112. Substrate 120 mechanically supports and electrically couples IC die 110, e.g., to a host component or substrate 299, which may be a system substrate, such as a motherboard or other PCB. IC die 110 (and device layer 115 through metallization structure 212 of and through interconnect section 112) may be coupled through package substrate 120 to a power supply on or through system substrate 299. Package substrate 120 may be coupled to system substrate 299 by any suitable means. In some embodiments, package substrate 120 is soldered to system substrate 299. In some embodiments, substrate 120 is a land-grid array (LGA) package substrate, and substrate 120 is affixed in a socket that is coupled to system substrate 299 with solder. Package substrate 120 and system substrate 299 may be coupled with other suitable structures.

Lid 140 may be of a thermally conductive material, such as a metal (e.g., stainless steel, aluminum, or copper). Lid 140 may be an integrated heat spreader and may be fastened or otherwise connected to IC device 200 and heat spreader die 130 by any suitable means.

FIG. 2B illustrates IC device 200 with thermal ground layer 101 over hotspots 103 in core 113. Hotspots 103 are illustrated with dashed lines under layer 101. Thermal sensors 150 are located adjacent thermal ground layer 101, laterally adjacent and above hotspots 103. In some embodiments, a larger thermal ground layer 101 spans beyond the edges of core 113 and over an area greater than the area of core 113. In some embodiments, a larger thermal ground layer 101, for example, over I/O regions 114, is not necessary. In some embodiments, thermal ground layer 101 is over only a portion of core 113, e.g., where hotspots 103 are modeled or otherwise expected to be. Thermal ground layer 101 may be located wherever is suitable, for example, wherever is convenient or necessary to dissipate heat.

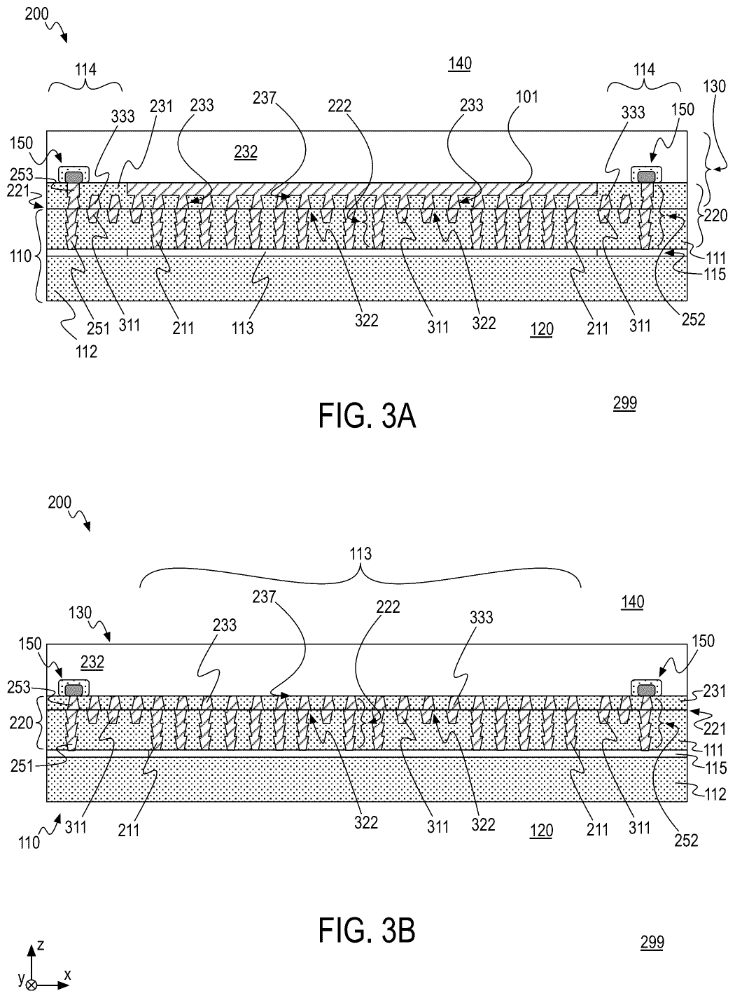

FIGS. 3A and 3B illustrate cross-sectional profile views of IC device 200 with heat spreader die 130, including thermal ground layer 101, coupled to device layer 115 by an array of thermal pillars 222, in accordance with some embodiments. FIG. 3A shows carrier or heat spreader die 130 with thermal ground layer 101 bonded to IC die 110 by a direct bond at interface 221. For example, metallization features on abutting surfaces of dies 110, 130 may be metallurgically interdiffused (e.g., thermal pillars 211 with pillars 233 and pillars 251 with pillars 253). In some embodiments, IC die 110 and carrier die 130 are hybrid bonded at interface 221. In some such embodiments, insulator or dielectric material 231 (e.g., between pillars 233 or between pillars 233, 253) is chemically bonded to insulator or dielectric material of an upper surface of interconnect section 111 (e.g., between pillars 211 or between pillars 211, 251), for example, via Si—O—Si condensation bonds.

The direct bonds between thermal pillars 211, 233 form thermal pillars 222. Each of thermal pillars 222 includes an upper portion (e.g., pillar 233) in die 130 (adjacent layer 101 and/or layer 232) and a lower portion (e.g., pillar 211) in die 110 adjacent device layer 115, with the upper and lower portions coupled by a direct bond. Thermal pillars 222 in and through dielectric section 220 contact thermal ground layer 101 at upper edge 237 and contact device layer 115. The lateral edges of thermal ground layer 101 are vertically aligned with the lateral edges of core 113 in device layer 115. In some embodiments, thermal ground layer 101 extends beyond the edges of core 113, e.g., over I/O regions 114. In some embodiments, thermal ground layer 101 is over only a portion of core 113, e.g., only a portion containing hotpots (or containing heat-generating regions that would have hotpots but for thermal ground layer 101 and thermal pillars 222).

IC device 200 and hybrid bond interface 221 may include additional structures not thermally or electrically connected to one or both of device layer 115 and/or thermal ground layer 101 or crystalline layer 232, e.g., dummy hybrid bond pads 311, 333. Rather than extending through interconnect section 111 or dielectric material 231, bond pads 311, 333 may be in only an upper or last metal layer of respective dies 110, 130. In some embodiments, hybrid bond interface 221 includes metallurgically interdiffused hybrid bond pads 311, 333 on dies 110, 130, respectively.

IC and carrier dies 110, 130 in IC device 200 may have a slight misalignment 322 at hybrid bond interface 221, which may be an indication of a hybrid bond. For example, the dielectric material of interconnect section 111 and dielectric material 231 may be chemically bonded and substantially continuous at hybrid bond interface 221, and pillars 211, 233; pillars 251, 253; and bond pads 311, 333 may be metallurgically interdiffused across bond interface 221. A slight misalignment 322 of metallization features (e.g., pillars 211, 233; pillars 251, 253; or bond pads 311, 333) may distinguish hybrid bond interface 221 within dielectric section 220. Such a lateral misalignment 322 would only be of a fraction of the width or radius of the metallization features, such that dies 110, 130 (and layers 115, 101) are still thermally coupled.

The location of hybrid bond interface 221 along a height of thermal pillars 222 may also be characterized by the differing profiles of thermal pillars 211, 233 (or pillars 251, 253 or pads 311, 333) in dies 110, 130, which may indicate a build-up direction towards hybrid bond interface 221. For example, pillars 211, 233 may have a widening or flaring in a build-up direction towards interface 221 (or a taper pointing away from interface 221). In some embodiments, metallization features in dies 110, 130 have a substantially vertical profile.

At least some of thermal pillars 251, 253 (coupling thermal sensors 150 to device layer 115 and IC die 110) may be the same or substantially similar to thermal pillars 211, 233. Others of pillars 251, 253 may be at least electrically different, e.g., not electrically grounded. Thermal sensors 150 may have multiple electrical terminals (and so potentially multiple thermal pillars 253), and while at least one pillar 253 per sensor 150 may be electrically grounded, any other terminals and pillars 253 may be at another voltage to properly bias sensor 150. Each pair of thermal pillars 251, 253, stacked and coupled end to end, together form a thermal pillar 252 with a height equal to the sum of the heights of thermal pillars 251, 253.

Thermal sensors 150 are in crystalline layer 232 of die 130, which may provide multiple benefits. Thermal sensors 150 in layer 232 of die 130 (above, rather than in, device layer 115 of die 110) conserves area in device layer 115. Thermal sensors 150 above, rather than in, device layer 115 allows for thermal coupling of sensors 150 to a point in device layer 115 (e.g., an expected hotspot) by thermal pillars 251, 253 rather than through a thermally insulating dielectric in layer 115. Locating thermal sensors 150 in crystalline layer 232 may also allow for a superior structure of sensor 150, e.g., a structure that provides better sensing performance and that occupies a smaller footprint.

Thermal sensors 150 may be thermal diodes, and a diode in crystalline layer 232 may be more compact laterally and may be a vertical diode, which may have a higher ideality factor. A thermal sensing diode may leverage the diode's temperature response according to a diode law, e.g., the Shockley diode equation, that relates the diode's voltage drop given a current through the diode (or the diode's current given a voltage across the diode). With the proper bias, a diode's voltage or current varies proportionally with a change in temperature. The diode's voltage or current also depends on the diode's ideality factor, which may be lower and less predictable for a lateral diode in device layer 115. A vertical-diode structure for sensor 150 (with one of a p- or n-type region over the other) in layer 232 allows for a relatively large p-n junction for a given footprint (e.g., a horizontal plane occupying the entirety of the footprint) and a relatively small portion of an STI at that p-n junction. A lateral diode in device layer 115 on the other hand has a p-n junction in a vertical plane with the plane's height limited by the STI height (e.g., depth). For a same sized p-n junction, a lateral diode may have to take up a much larger footprint. Also, a larger area of the lateral diode may be along the STI. Such an STI around a thermal sensor 150 may have many imperfections along the STI-semiconductor interface from having been etched and then from the deposition of the isolation material, e.g., an oxide. These imperfections may cause unpredictable trapping (and subsequent unpredictable recombinations) of charge carriers, which may then result in random variation in the output (e.g., the diode voltage or current) of thermal sensor 150. This variation is uncoupled from the temperature of thermal sensor 150 and must be accounted for by increased guard banding. For example, any system using the output of thermal sensor 150 to throttle the power, and so maintain the temperature, of IC device 200 must use a larger safety margin to a critical temperature in order to preserve the device's reliability.

Thermal diode sensors 150 may employ other structures. In some embodiments, one or more sensors 150 are diode-connected transistors, e.g. bipolar junction transistors (BJT). For example, sensor 150 may be a BJT with base and collector electrically connected. Sensor 150 may have these or one or more other structures. Sensor 150 may be electrically connected to circuitry, e.g., in device layer 115, that utilizes the temperature data provided by sensor 150, for example, to throttle electrical power to and through device layer 115.

FIG. 3B illustrates heat spreader die 130 hybrid bonded to IC die 110, but without a copper (or other metal, etc.) thermal ground layer 101. An array of thermal pillars 222 extends through dielectric section 220 and terminates at edge 237 of dielectric section 220. Pillars 222 are in contact with device layer 115 at a lower end of pillar 222. Pillars 222 are in contact with crystalline layer 232 at an upper end of pillar 222. In some embodiments, the array of thermal pillars 222 extends through dielectric section 220 and terminates beyond edge 237 of dielectric section 220, within a thickness (e.g., in the z direction) of crystalline layer 232. Pillars 222 are in contact with device layer 115 at a lower end and with crystalline layer 232 at an upper end.

Though perhaps not as electrically conductive as, e.g., copper (or another metal, etc.), crystalline layer 232 may be a thermal ground layer 101. As with a thermal ground layer 101 of, for example, copper (or another metal), crystalline layer 232 may have a sufficient thermal conductance to aid in dissipation of heat upward from device layer 115 to lid 140 as well as for the quick transfer of heat laterally. Advantageously, crystalline layer 232 may be thick enough (e.g., in the z direction) to provide a sufficient thermal conductance laterally, but not so thick to inhibit heat transfer vertically. A less thermally conductive material (such as silicon, relative to, e.g., copper) may need to be correspondingly thicker to convey thermal energy laterally at a sufficient rate. However, as the thickness of crystalline layer 232 may have already been present (and sufficient or satisfactory) in the heat transfer stack up from device layer 115 to lid 140, the absence of a layer of metal as a thermal ground layer 101 may not be overly detrimental. For example, with a sufficiently large quantity of thermal pillars 222 of sufficiently large cross-sectional area, heat may be dissipated away from device layer 115 at a sufficient rate, and any degradation in lateral thermal conduction may be satisfactorily negligible. In some embodiments, the absence of a metal in thermal ground layer 101 is advantageous, as thermal conductance outward from device layer is sufficient, and manufacturing costs (e.g., of materials and in processing time) are reduced.

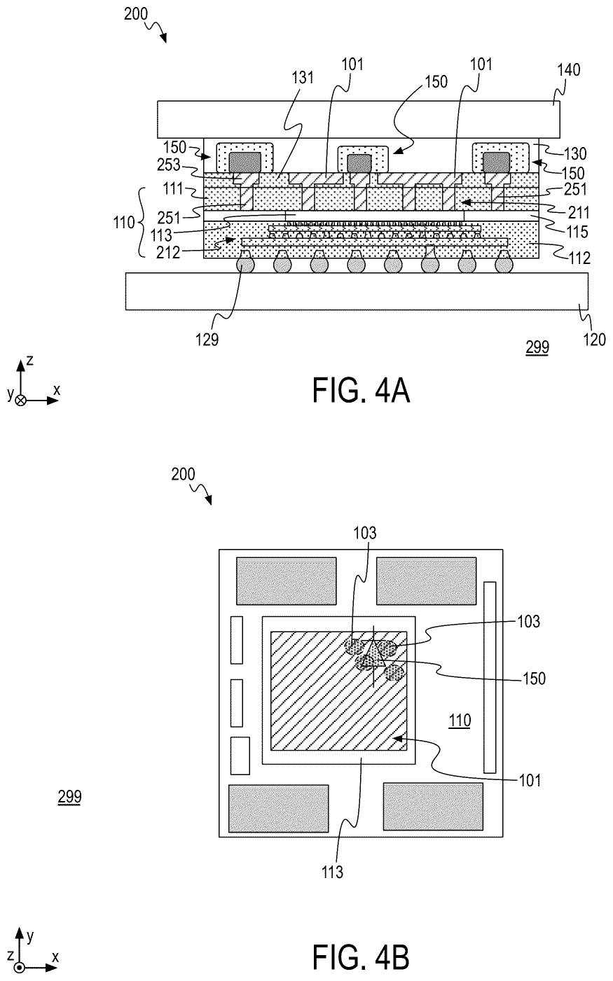

FIGS. 4A and 4B illustrate cross-sectional profile and plan views of IC device 200 with temperature sensors 150 over thermal ground layer 101 and core 113 in device layer 115, in accordance with some embodiments. FIG. 4A shows temperature sensor 150 over core 113 (and potential hotspots) in device layer 115 with thermal ground layer 101 between sensor 150 and device layer 115. Placement of thermal sensor 150 over a thermal hotspot facilitates better detection of hotspot temperature, as thermal pillars 251, 253 may be positioned in contact with both hotspot and sensor 150, and sensor 150 and the hotspot may be directly thermally coupled (rather than through a less thermally conductive dielectric material in device layer 115).

Placement of thermal sensor 150 over thermal ground layer 101 may allow for other electrical connections to sensor 150, e.g., conservation or flexibility of thermal pillar usage. For sensors 150 to the side of, instead of over, thermal ground layer 101, sensor 150 may contact at least two thermal pillars 253, as described elsewhere herein. For example, one thermal pillar 253 may contact one electrical terminal of sensor 150 (coupling that terminal to electrical ground), and another thermal pillar 253 may contact another electrical terminal of sensor 150 (biasing that terminal with a proper voltage or current). For sensors 150 over and on thermal ground layer 101, one electrical terminal of sensor 150 may contact (and be coupled to electrical ground by) thermal ground layer 101, and another electrical terminal of sensor 150 may contact (and be biased by) another thermal pillar 253). This contacting of a thermal diode (or BJT) sensor 150 may be implemented by breaking up thermal ground layer 101, e.g., with a ring-shaped gap separating the anode and cathode of sensor 150. Thermal (and electrical) ground layer 101 contacts one of the terminals, and thermal pillar 253 contacts the other (e.g., through the ring-shaped gap).

FIG. 4B illustrates that placement of thermal sensor 150 over thermal ground layer 101 and hotspots 103 not only facilitates better detection of hotspot temperature, such placement also saves area, e.g., of core 113. Rather than locating thermal sensor 150 next to thermal hotspots 103 and taking additional area in core 113, FIG. 4B shows thermal diode (or BJT) sensor 150 placed over thermal hotspots 103, saving area. This placement allows for building a three-dimensional (3D), analog thermal sensor 150. The same number of temperature sensors 150 can be deployed using less area, or the same area can host more sensors 150. Multiple temperature sensors 150 can be deployed in an array, and temperatures can be compared, including with their relative locations, which may allow for not just temperature information at sampled locations, but for a more complete picture of temperature and changes in temperature, e.g., both spatially and temporally.

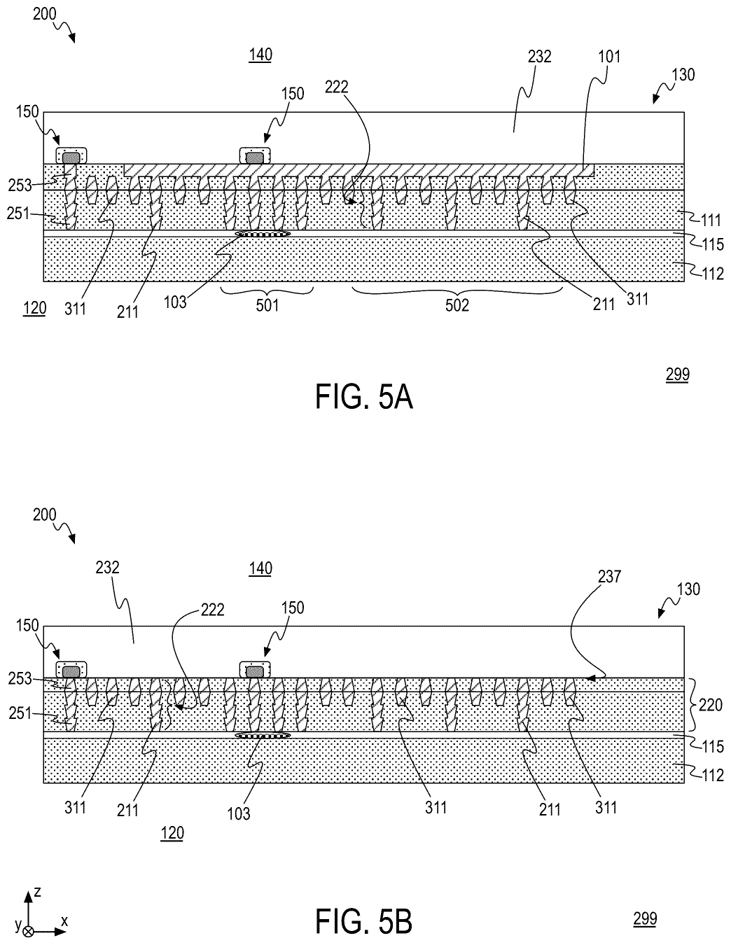

FIGS. 5A and 5B illustrate cross-sectional profile views of IC device 200 with heat spreader die 130, including temperature sensor 150 over thermal ground layer 101, coupled to device layer 115 by an array of thermal pillars 222, in accordance with some embodiments. FIG. 5A shows thermal sensor 150 built in carrier die 130 and placed directly over thermal hotspot 103, which allows for precise detection of the temperature of hotspot 103. Thermal sensors 150 are made from implanted junctions in crystalline layer 232 of carrier die 130, which enables vertical conduction of thermal energy from hotspot 103 through thermal pillars 251, 253 to sensor 150. (Sensor 150 over thermal ground layer 101 may be coupled to device layer 115 by thermal pillars 251, 253, e.g., through a gap in thermal ground layer 101 just in front of or behind the viewing plane.) Vertical diode sensors 150 are nearly ideal (ideality factor n˜1) and are highly accurate thermal sensors 150 when combined with analog circuitry in device layer 115. The placement of thermal sensor 150 and thermal pillars 222, 251, 253 may be manual and/or as part of an automated place and route (APR) system. Such a system may involve conventional timing considerations (e.g., of parasitics and other geometries), thermal modeling and analysis, etc., and may be iterative. For example, an APR system may set an initial routing and placement, including of thermal pillars 222, 252 and thermal sensors 150, before then modeling thermal effects and re-routing and -placing. Thermal sensors 150 may be placed over expected hotspots 103, including more or additional sensors 150 over thermal ground layer 101. A base (or default) frequency or density of thermal pillars 222 may be distributed throughout the footprint or lateral area of core 113. Additional thermal pillars may be placed opportunistically by either APR or a fill algorithm should there be available empty space, and timing and thermal dissipation rechecked in the design signoff phase.

Thermal pillars 222 may be deployed at an increased frequency near expected hotspots 103, as in the example of FIG. 5A. A portion 501 of the array of thermal pillars 222 has a density of thermal pillars 222 greater than a density of thermal pillars 222 in portion 502 of the array of thermal pillars 222. Portion 501 includes thermal pillar 222 and/or 252 coupled to thermal sensor 150 over hotspot 103. Thermal sensor 150 ensures that thermal hotspot 103 will be well monitored for thermal runaway, and portion 501 may have greater density of thermal pillars 222 to aid in dissipation of heat away from hotspot 103 through pillars 222, to and through carrier die 130 and package lid 140, which may be an integrated heat spreader.

FIG. 5B illustrates heat spreader die 130 hybrid bonded to IC die 110, but without a metal thermal ground layer 101. An array of thermal pillars 222 extends through dielectric section 220 and terminates at edge 237 of dielectric section 220. Pillars 222 are in contact with device layer 115 at a lower end and with crystalline layer 232 at an upper end. In some embodiments, the array of thermal pillars 222 extends through dielectric section 220 and terminates beyond edge 237 of dielectric section 220, within a thickness (e.g., in the z direction) of crystalline layer 232. In such embodiments, pillars 222 are still in contact with device layer 115 at a lower end and with crystalline layer 232 at an upper end.

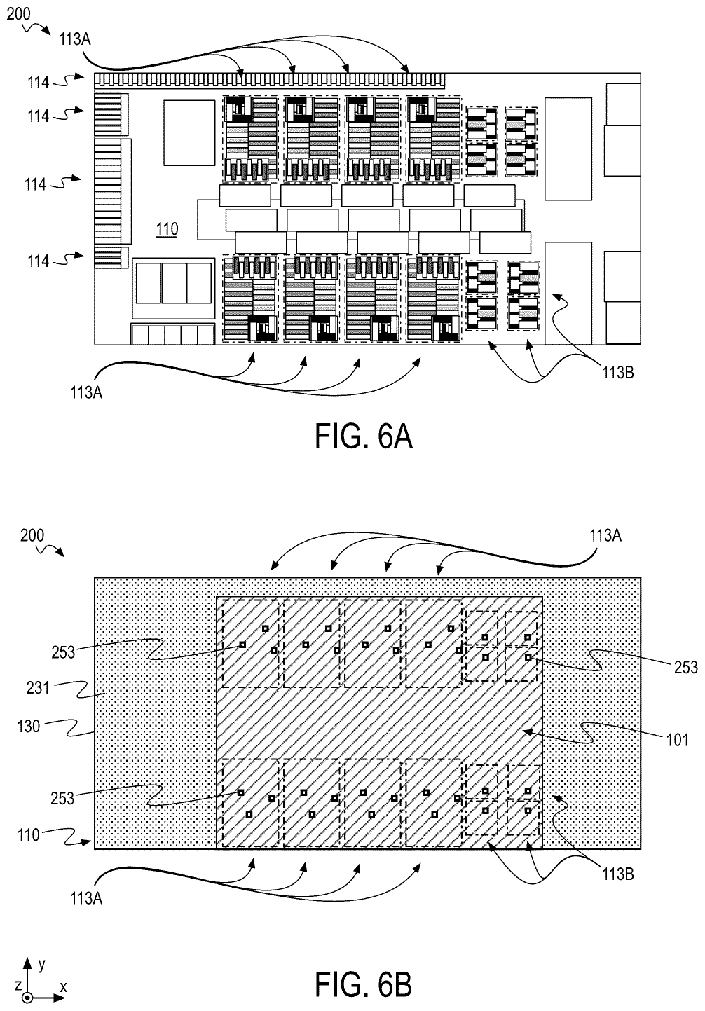

FIGS. 6A and 6B illustrate cross-sectional plan views of IC device 200, including thermal ground layer 101 over cores 113 in IC die 110, in accordance with some embodiments. To enable contacting of thermal sensing diodes (or BJT), and as described elsewhere herein, e.g., at least at FIG. 4A, thermal ground layer 101 may be broken up by ring-shaped gaps around thermal pillars 253 that may contact an electrical terminal (e.g., an anode or cathode) of a thermal diode. FIG. 6A shows a plan view of IC die 110 below thermal ground layer 101, including multiple larger cores 113A and multiple smaller cores 113B. I/O regions 114 are along some edges of die 110. FIG. 6B illustrates thermal ground layer 101 in heat spreader die 130, over IC die 110. Outlines of cores 113A, 113B are indicated by dashed lines. Thermal ground layer 101 is only needed and utilized over cores 113A, 113B. Dielectric material 231 can be seen to either side of layer 101. Thermal ground layer 101 does not extend to I/O regions 114 or substantially past cores 113A, 113B. Ring-shaped gaps around thermal pillars 253 allow for proper biasing of thermal sensors (not shown) above thermal ground layer 101. Thermal ground layer 101 may be electrically grounded and connected (e.g., electrically) to one electrical terminal of thermal sensors (not shown). Thermal pillars 253 may be connected (e.g., electrically) to the other electrical terminal of thermal sensors (not shown), for example, to bias the sensors, and the ring-shaped gaps around thermal pillars 253 allow for electrical isolation between electrical ground (e.g., thermal ground layer 101) and the bias on thermal pillars 253. Three ring-shaped gaps over each of larger cores 113A indicate the use of more thermal sensors for these higher performance cores 113A, which generate, and need to dissipate, more heat. Smaller cores 113B consume less electrical power, generate less heat, and only use a single thermal sensor per core 113B.

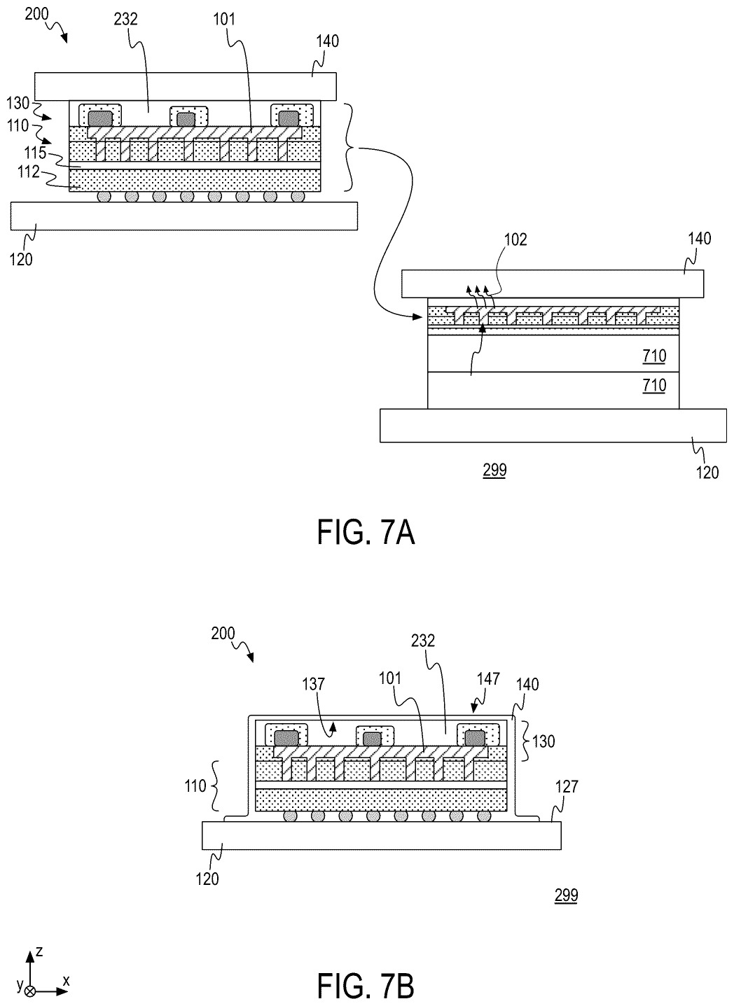

FIGS. 7A and 7B illustrate cross-sectional profile views of IC device 200, including with multiple dies 710 stacked over package substrate 120, in accordance with some embodiments. FIG. 7A shows IC device 200 with device layer 115 in a compute or processor die 110 thermally coupled to thermal ground layer 101 (and heat spreader die 130) and package lid 140. With a thermal ground layer 101, heat 102 can be conducted through compute die 110, and is not blocked by the dice 710 below. In fact, heat 102 from dice 710 below can also be effectively removed by high-performance compute die 110 and thermal ground layer 101.

FIG. 7B illustrates package lid 140 electrically grounded, e.g., connected at upper surface 127 of package substrate 120 to electrical ground of package substrate 120 and system substrate 299. Package lid 140 may be an integrated heat spreader that encapsulates dies 110, 130 (and, in some embodiments, one or more dies 710). Package lid 140 may be a heat sink relative even to thermal ground layer 101 within heat spreader die 130. Package lid 140 may help dissipate heat from die 110 to, e.g., a heat sink (not shown) that may contact upper surface 147 of lid 140. In some embodiments, package lid 140 dissipates heat from die 110 to substrates 120, 299. Thermal ground layer 101 (e.g., of copper) and thermal pillars 222 are connected to package electrical ground of package substrate 120 and system substrate 299, e.g., through metallization within interconnect section 112 of die 110, and crystalline layer 232 (of heat spreader die 130) is connected to package electrical ground by package lid 140 (e.g., through package substrate 120).

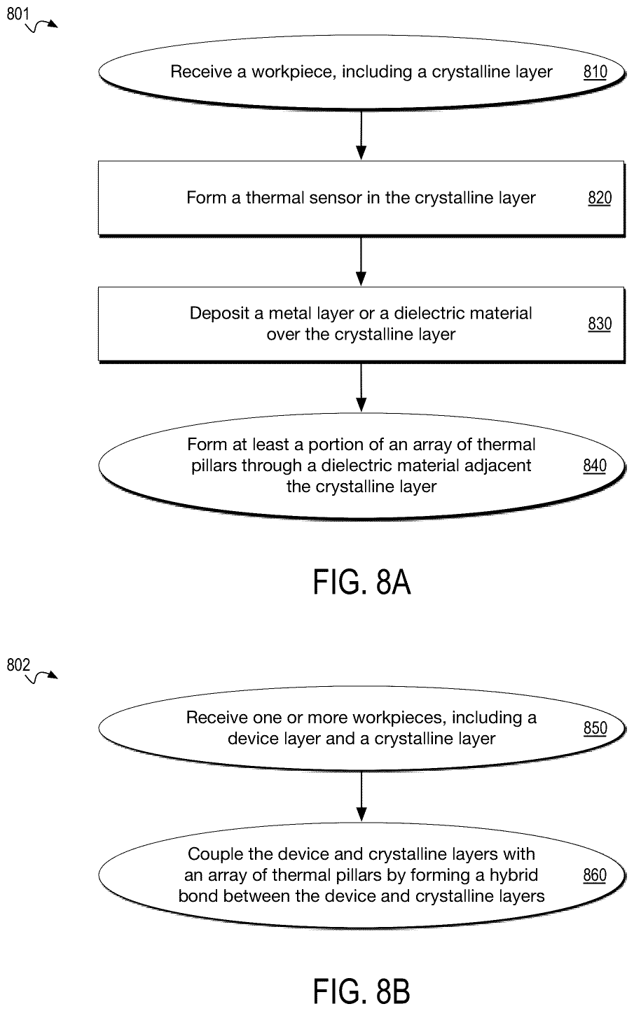

FIGS. 8A and 8B are flow charts of methods 801, 802 for forming an array of thermal pillars and coupling an IC device layer to a thermal ground layer with the array, in accordance with some embodiments. Methods 801, 802 include operations 810-860. Some operations shown in FIG. 8 are optional, such as those of methods or processes 801, which may precede methods or processes 802. Additional operations may be included. FIG. 8 shows an example sequence, but the operations can be done in other orders as well, and some operations may be omitted. Some operations can also be performed multiple times before other operations are performed. For example, multiple crystalline layer may be received, and multiple arrays of thermal pillars may be formed before device and crystalline layers are coupled. Some operations may be included within other operations so that the number of operations illustrated in FIGS. 8A and 8B are not a limitation of the methods 801, 802.

Methods 801 begin at operation 810, where a crystalline layer is received. The crystalline layer may be a semiconductor substrate, e.g., of silicon, or any suitable material, and may be a complete wafer or in the form of a die. The crystalline layer may advantageously thermally conductive, which may aid in dissipating thermal energy, e.g., heat, from an IC device layer to a heat spreader die. The crystalline layer or semiconductor substrate may be such a heat spreader die. Advantageously, the crystalline layer may be a suitable substrate, e.g., a semiconductor substrate, for forming thermal sensors, such as thermal diodes (or BJT). In some embodiments, the crystalline layer is in an IC die with devices, e.g., transistor devices, on or in the layer.

Methods 801 continue at operation 820, where a thermal sensor is formed in the crystalline layer. The thermal sensor may have any suitable structure, including that of a thermal sensing diode. Such a diode may have an output voltage or current that varies predictably with temperature, e.g., according to the Shockley diode equation.

The thermal sensor may be formed in a conventional or convenient manner, for example, by forming one or more p-n junctions (e.g., a diode) with abutting p- and n-type regions in a semiconductor substrate. In some embodiments, a p-type (or n-type) well is formed by doping the semiconductor with an acceptor (or donor) impurity. In some such embodiments, a n-type (or p-type) region is formed in the p-type (or n-type) well by doping the semiconductor with a donor (or acceptor) impurity. A BJT structure may be formed for the sensor, as a BJT can later be wired as a diode (e.g., by electrically connecting the base and collector terminals).

An isolation region, such as an STI, may be formed around the footprint of the sensor prior to doping the semiconductor substrate. Such isolation may ensure that the sensor output, e.g., a voltage or current, is proportional to the temperature of the sensor and not overly susceptible to leakage to or from adjacent structures or regions in the substrate. Advantageously, the STI (or other isolation feature) will be minimally border the p-n junction, as the etching of the STI trench and subsequent isolation deposition may form traps for charge carriers. Such carrier trapping and subsequent carrier recombination may cause random or otherwise unpredictable fluctuations in the sensor output. The isolation deposition may be a thick growth of an oxide, which may result in an uneven surface finish. A chemical-mechanical planarization (CMP) or polish may be employed to provide a smooth or flat surface for following operations.

The thermal sensor, e.g., diode, may advantageously be formed with structure having a high ideality factor, for example, of approximately n−1. Such a structure may be of a vertical diode with a p-n junction in a substantially horizontal plane between the n- and p-type regions. The sensor will also advantageously not be overly susceptible to charge carrier trapping of, e.g., an isolation trench (such as an STI).

Electrical connections to the sensor may be made during or between other operations.

Methods 801 continue at operation 830, where a layer of metal or dielectric material is formed over the crystalline layer. A dielectric material may be formed by any suitable means and of any suitable materials, such as a low-k insulator. Such a material may be formed or deposited, e.g., thermally grown as a thermal oxidation of or over the substrate, which may be an IC die or carrier die. The dielectric material may be formed in a single or in multiple operations and may be planarized to provide a smooth or flat upper surface. The dielectric material may advantageously be capable of bonding with a same or complementary material later. The dielectric material may advantageously be capable of supporting and insulating or isolating electrical lines and vias (e.g., metallization structures).

In some embodiments, the crystalline layer is a carrier wafer or heat spreader die, and a metal layer is formed in a void formed in the dielectric material such that the layer of metal contacts the crystalline layer over the area of the metal layer. Such formation, e.g., deposition, of metal may advantageously contact a large area of the crystalline layer, for example, after a thorough removal of dielectric material over the crystalline layer. In some embodiments, gaps in the deposition (or other formation) of the metal may be maintained, e.g., with a mask material, over thermal sensors in the crystalline layer to ensure proper biasing of the sensor. For example, an anode and cathode of a thermal diode will not both be in contact with the metal layer, which may become a thermal ground layer. In some such embodiments, one electrical terminal of a thermal sensor may be filled (or otherwise covered) with metal, and the gaps between the electrical terminals of the thermal sensor may be left uncovered (or covered with a masking material). Any suitable means may be employed, e.g., a damascene or dual-damascene process, or subtractive etch process, and any suitable material or metal, such as copper, may be formed. In some embodiments, multiple metals are deposited, e.g., a liner or seed metal first, and then a fill or bulk metal over the liner or seed metal. The liner metal may induce a metal silicide formation in the crystalline layer. In some embodiments, operations 830 and 840 are performed concurrently or iteratively.

Methods 801 continue at operation 840, where an array of thermal pillars is formed through a dielectric material. The thermal pillars may be formed through dielectric material over either of an IC die or a carrier die. Such thermal pillars in one die may later be bonded to thermal pillars in the other die. The thermal pillars may be formed in any satisfactory manner and of any satisfactory material, such as a means and of a metal similar to those of operation 830. For example, thermal pillars (e.g., vias through the dielectric material) may be formed of copper using a damascene process where dielectric material is removed and replaced by one or more deposited metals. Thermal pillars may be formed in the IC die in and through dielectric material and contacting the device layer with one end (e.g., with the other end available for bonding with the carrier die). Thermal pillars may be formed in the carrier die in and through dielectric material, e.g., contacting the crystalline layer with one end (and with the other end available for bonding with the IC die). In embodiments with a layer of metal contacting the crystalline layer, at least some of the thermal pillars contact the layer of metal with one end (e.g., with the other end available for bonding with the IC die. A planarization process, such as a CMP, may remove excess metal. At the completion of operation 840, one or more crystalline layers (e.g., in an IC die or a handle or carrier die) may have a smooth upper surface finish with a dielectric material substantially planar with the exposed upper surfaces of an array of metal thermal pillars within and extending through the dielectric material.

Methods 802 begin at operation 850, where device and crystalline layers are received. The device layer may include a crystalline layer, and both of the device and crystalline layers may have substantially planar exposed upper surfaces of a dielectric material with an array of metal thermal pillars within and extending through the dielectric material. The arrays of metal thermal pillars at the surface of the dielectric materials may be complementary, e.g., with substantially matching pillar geometries and pitches.

Methods 802 continue at operation 860, where a hybrid bond is formed between the device and crystalline layers, and the device and crystalline layers are coupled by an array of thermal pillars between the layers. In some embodiments, the exposed and planarized surfaces (e.g., of dielectric and metal) over the device and crystalline layers may be direct bonded, including hybrid bonded. Direct bonding of the IC and carrier wafers or dice may be at least metal-to-metal, for example, during which metallization structures sinter. In some embodiments, a hybrid bond is formed between both metallization features (e.g., by metal interdiffusion) and between dielectric materials (e.g., by Si—O—Si condensation bonds). Direct bonding may allow for finer pitch features of the IC and carrier dies and for coupling the dies at lower temperatures. For example, thermo-compression bonding may be at low temperatures (e.g., with sintering below the melting temperature(s) of the pillars). Direct bonding at room temperature (e.g., with compression only) is also possible. Bonding finer pitch features (for example, of very narrow pillars, finer than practicable by soldering) may require correspondingly more precise alignment before bonding. Direct bonding, particularly at lower temperatures, may benefit from pre-processing, for example, a plasma clean, to activate one or more surfaces for bonding. Selective heating (e.g., as an anneal) may be employed to strengthen a bond (e.g., by interdiffusion between pillars). The selective heating may employ a laser or other means to localize heating to a specific region or structure (e.g. the metal pillars to be interdiffused).

Following hybrid bonding of and between the device layer (e.g., in an IC die) and the crystalline layer (e.g., in a carrier or heat spreader die), the bonded (now taller) thermal pillars extend through a continuous dielectric section between the device layer and the crystalline layer, and both ends of the now-taller thermal pillars contact the device layer or the crystalline layer.

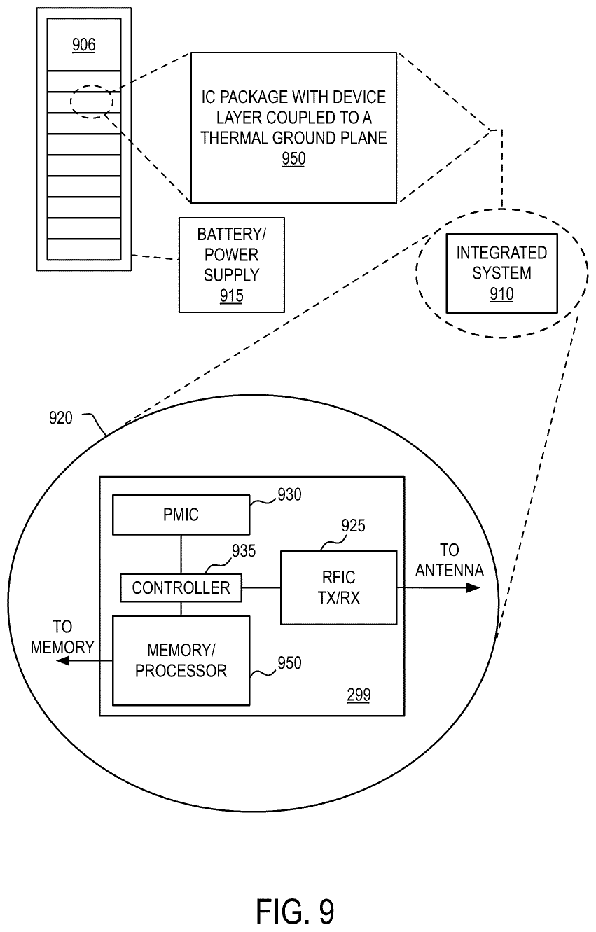

FIG. 9 illustrates a diagram of an example data server machine 906 employing an IC device having an array of thermal pillars contacting, and coupling between, a device layer and a heat spreader layer, in accordance with some embodiments. Server machine 906 may be any commercial server, for example, including any number of high-performance computing platforms disposed within a rack and networked together for electronic data processing, which in the exemplary embodiment includes one or more devices 950 having an array of thermal pillars coupling a device layer and a heat spreader layer.

Also as shown, server machine 906 includes a battery and/or power supply 915 to provide power to devices 950, and to provide, in some embodiments, power delivery functions such as power regulation. Devices 950 may be deployed as part of a package-level integrated system 910. Integrated system 910 is further illustrated in the expanded view 920. In the exemplary embodiment, devices 950 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 950 is a microprocessor including a static RAM (SRAM) cache memory. As shown, device 950 may be an IC device having an array of thermal pillars coupling a device layer and a heat spreader layer, as discussed herein. Device 950 may be further coupled to (e.g., communicatively coupled to) a board, an interposer, or a substrate 299 along with, one or more of a power management IC (PMIC) 930, RF (wireless) IC (RFIC) 925 including a wideband RF (wireless) transmitter and/or receiver (TX/RX) (e.g., including a digital baseband and an analog front end module further includes a power amplifier on a transmit path and a low noise amplifier on a receive path), and a controller 935 thereof. In some embodiments, RFIC 925, PMIC 930, controller 935, and device 950 include an array of thermal pillars between a device layer and a heat spreader layer.

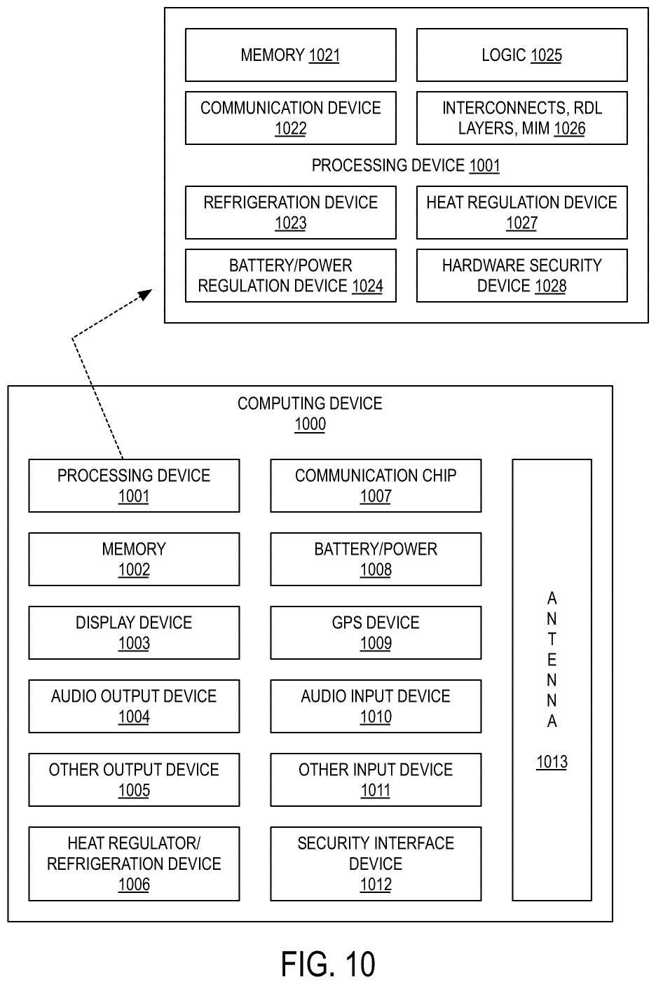

FIG. 10 is a block diagram of an example computing device 1000, in accordance with some embodiments. For example, one or more components of computing device 1000 may include any of the devices or structures discussed herein. A number of components are illustrated in FIG. 10 as being included in computing device 1000, but any one or more of these components may be omitted or duplicated, as suitable for the application. In some embodiments, some or all of the components included in computing device 1000 may be attached to one or more printed circuit boards (e.g., a motherboard). In some embodiments, various ones of these components may be fabricated onto a single system-on-a-chip (SoC) die. Additionally, in various embodiments, computing device 1000 may not include one or more of the components illustrated in FIG. 10, but computing device 1000 may include interface circuitry for coupling to the one or more components. For example, computing device 1000 may not include a display device 1003, but may include display device interface circuitry (e.g., a connector and driver circuitry) to which display device 1003 may be coupled. In another set of examples, computing device 1000 may not include an audio output device 1004, other output device 1005, global positioning system (GPS) device 1009, audio input device 1010, or other input device 1011, but may include audio output device interface circuitry, other output device interface circuitry, GPS device interface circuitry, audio input device interface circuitry, audio input device interface circuitry, to which audio output device 1004, other output device 1005, GPS device 1009, audio input device 1010, or other input device 1011 may be coupled.

Computing device 1000 may include a processing device 1001 (e.g., one or more processing devices). As used herein, the term “processing device” or “processor” indicates a device that processes electronic data from registers and/or memory to transform that electronic data into other electronic data that may be stored in registers and/or memory. Processing device 1001 may include a memory 1021, a communication device 1022, a refrigeration device 1023, a battery/power regulation device 1024, logic 1025, interconnects 1026 (i.e., optionally including redistribution layers (RDL) or metal-insulator-metal (MIM) devices), a heat regulation device 1027, and a hardware security device 1028.

Processing device 1001 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 1000 may include a memory 1002, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1002 includes memory that shares a die with processing device 1001. This memory may be used as cache memory and may include embedded dynamic random-access memory (eDRAM) or spin transfer torque magnetic random-access memory (STT-MRAM).

Computing device 1000 may include a heat regulation/refrigeration device 1006. Heat regulation/refrigeration device 1006 may maintain processing device 1001 (and/or other components of computing device 1000) at a predetermined low temperature during operation.

In some embodiments, computing device 1000 may include a communication chip 1007 (e.g., one or more communication chips). For example, the communication chip 1007 may be configured for managing wireless communications for the transfer of data to and from computing device 1000. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 1007 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1007 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1007 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1007 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1007 may operate in accordance with other wireless protocols in other embodiments. Computing device 1000 may include an antenna 1013 to facilitate wireless communications and/or to receive other wireless communications (such as AM or FM radio transmissions).

In some embodiments, communication chip 1007 may manage wired communications, such as electrical, optical, or any other suitable communication protocols (e.g., the Ethernet). As noted above, communication chip 1007 may include multiple communication chips. For instance, a first communication chip 1007 may be dedicated to shorter-range wireless communications such as Wi-Fi or Bluetooth, and a second communication chip 1007 may be dedicated to longer-range wireless communications such as GPS, EDGE, GPRS, CDMA, WiMAX, LTE, EV-DO, or others. In some embodiments, a first communication chip 1007 may be dedicated to wireless communications, and a second communication chip 1007 may be dedicated to wired communications.

Computing device 1000 may include battery/power circuitry 1008. Battery/power circuitry 1008 may include one or more energy storage devices (e.g., batteries or capacitors) and/or circuitry for coupling components of computing device 1000 to an energy source separate from computing device 1000 (e.g., AC line power).

Computing device 1000 may include a display device 1003 (or corresponding interface circuitry, as discussed above). Display device 1003 may include any visual indicators, such as a heads-up display, a computer monitor, a projector, a touchscreen display, a liquid crystal display (LCD), a light-emitting diode display, or a flat panel display, for example.

Computing device 1000 may include an audio output device 1004 (or corresponding interface circuitry, as discussed above). Audio output device 1004 may include any device that generates an audible indicator, such as speakers, headsets, or earbuds, for example.

Computing device 1000 may include an audio input device 1010 (or corresponding interface circuitry, as discussed above). Audio input device 1010 may include any device that generates a signal representative of a sound, such as microphones, microphone arrays, or digital instruments (e.g., instruments having a musical instrument digital interface (MIDI) output).

Computing device 1000 may include a GPS device 1009 (or corresponding interface circuitry, as discussed above). GPS device 1009 may be in communication with a satellite-based system and may receive a location of computing device 1000, as known in the art.

Computing device 1000 may include other output device 1005 (or corresponding interface circuitry, as discussed above). Examples of the other output device 1005 may include an audio codec, a video codec, a printer, a wired or wireless transmitter for providing information to other devices, or an additional storage device.

Computing device 1000 may include other input device 1011 (or corresponding interface circuitry, as discussed above). Examples of the other input device 1011 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1000 may include a security interface device 1012. Security interface device 1012 may include any device that provides security measures for computing device 1000 such as intrusion detection, biometric validation, security encode or decode, access list management, malware detection, or spyware detection.

Computing device 1000, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1A-10. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes an integrated circuit (IC) device layer between a first dielectric section and a second dielectric section, the IC device layer coupled to a metallization structure within the first dielectric section, a crystalline layer, wherein the second dielectric section is between the IC device layer and the crystalline layer, and an array of thermal pillars extending through the second dielectric section, the array of thermal pillars in contact with the IC device layer and terminating at an edge of the second dielectric section or within a thickness of the crystalline layer.

In one or more second embodiments, further to the first embodiments, the thermal pillars contact and terminate at a thermal ground layer between the second dielectric section and the crystalline layer.

In one or more third embodiments, further to the first or second embodiments, the thermal ground layer includes predominantly copper.

In one or more fourth embodiments, further to the first through third embodiments, the apparatus also includes a thermal sensor, wherein a first electrode of the thermal sensor is in, or thermally coupled to, the IC device layer.

In one or more fifth embodiments, further to the first through fourth embodiments, the thermal sensor is in the crystalline layer.

In one or more sixth embodiments, further to the first through fifth embodiments, the thermal sensor is thermally coupled to the IC device layer by an individual one of the thermal pillars.

In one or more seventh embodiments, further to the first through sixth embodiments, an individual one of the thermal pillars includes a first portion adjacent the crystalline layer and a second portion adjacent the IC device layer, and the first and second portions are coupled by a direct bond.

In one or more eighth embodiments, further to the first through seventh embodiments, the second dielectric section includes a first region, a second region, and a hybrid bond along an interface between the first and second regions, wherein the first region is adjacent the crystalline layer, and the second region is adjacent the IC device layer.

In one or more ninth embodiments, further to the first through eighth embodiments, a first portion of the array has a first density of thermal pillars, a second portion of the array has a second density of thermal pillars, the first density is greater than the second density, and the first portion includes an individual one of the thermal pillars coupled to a thermal sensor.

In one or more tenth embodiments, further to the first through ninth embodiments, the crystalline layer includes predominantly silicon.

In one or more eleventh embodiments, an apparatus includes a substrate, an integrated circuit (IC) device layer between first and second dielectric sections, wherein the first dielectric section is between the IC device layer and the substrate, and a metallization structure within the first dielectric section couples the IC device layer to the substrate, an array of thermal pillars extending through the second dielectric section, wherein first ends of the thermal pillars contact the IC device layer, and second ends of the thermal pillars contact a crystalline layer or a thermal ground layer between the second dielectric section and the crystalline layer, and a lid over the crystalline layer, wherein the lid includes predominantly a metal.

In one or more twelfth embodiments, further to the eleventh embodiments, the IC device layer is coupled to a power supply by the metallization structure.

In one or more thirteenth embodiments, further to the eleventh or twelfth embodiments, the apparatus also includes an IC die between the first dielectric section and the substrate.

In one or more fourteenth embodiments, further to the eleventh through thirteenth embodiments, the crystalline layer includes a thermal sensor coupled to the IC device layer by a thermal pillar.

In one or more fifteenth embodiments, further to the eleventh through fourteenth embodiments, the thermal ground layer includes predominantly copper, and the lid and the thermal ground layer are coupled to an apparatus electrical ground.

In one or more sixteenth embodiments, a method includes receiving a device layer and a crystalline layer, and coupling the device layer and the crystalline layer with an array of thermal pillars therebetween by forming a hybrid bond between the device layer and the crystalline layer, wherein the thermal pillars extend through a dielectric section between the device layer and the crystalline layer, and first ends of the thermal pillars contact the device layer, and second ends of the thermal pillars contact the crystalline layer or a layer of metal between the dielectric section and the crystalline layer.

In one or more seventeenth embodiments, further to the sixteenth embodiments, the method also includes forming a thermal sensor in the crystalline layer.

In one or more eighteenth embodiments, further to the sixteenth or seventeenth embodiments, forming the hybrid bond thermally and electrically couples the thermal sensor to the device layer.

In one or more nineteenth embodiments, further to the sixteenth through eighteenth embodiments, the method also includes depositing a layer of metal or a dielectric material over the crystalline layer, at least some of the thermal pillars to be connected to the layer of metal or the crystalline layer.

In one or more twentieth embodiments, further to the sixteenth through nineteenth embodiments, the method also includes forming a portion of the array of thermal pillars in a dielectric material adjacent the dielectric section or the crystalline layer.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
an integrated circuit (IC) device layer between a first dielectric section and a second dielectric section, the IC device layer coupled to a metallization structure within the first dielectric section;
a crystalline layer, wherein the second dielectric section is between the IC device layer and the crystalline layer; and
an array of thermal pillars extending through the second dielectric section, the array of thermal pillars in contact with the IC device layer and terminating at an edge of the second dielectric section or within a thickness of the crystalline layer.

2. The apparatus of claim 1, wherein the thermal pillars contact and terminate at a thermal ground layer between the second dielectric section and the crystalline layer.

3. The apparatus of claim 2, wherein the thermal ground layer is comprised predominantly of copper.

4. The apparatus of claim 1, further comprising a thermal sensor, wherein a first electrode of the thermal sensor is in, or thermally coupled to, the IC device layer.

5. The apparatus of claim 4, wherein the thermal sensor is in the crystalline layer.

6. The apparatus of claim 5, wherein the thermal sensor is thermally coupled to the IC device layer by an individual one of the thermal pillars.

7. The apparatus of claim 1, wherein an individual one of the thermal pillars comprises a first portion adjacent the crystalline layer and a second portion adjacent the IC device layer, and the first and second portions are coupled by a direct bond.

8. The apparatus of claim 7, wherein the second dielectric section comprises a first region, a second region, and a hybrid bond along an interface between the first and second regions, wherein the first region is adjacent the crystalline layer, and the second region is adjacent the IC device layer.

9. The apparatus of claim 1, wherein a first portion of the array has a first density of thermal pillars, a second portion of the array has a second density of thermal pillars, the first density is greater than the second density, and the first portion comprises an individual one of the thermal pillars coupled to a thermal sensor.

10. The apparatus of claim 1, wherein the crystalline layer is comprised predominantly of silicon.

11. An apparatus, comprising:
a substrate;
an integrated circuit (IC) device layer between first and second dielectric sections, wherein the first dielectric section is between the IC device layer and the substrate, and a metallization structure within the first dielectric section couples the IC device layer to the substrate;
an array of thermal pillars extending through the second dielectric section, wherein first ends of the thermal pillars contact the IC device layer, and second ends of the thermal pillars contact a crystalline layer or a thermal ground layer between the second dielectric section and the crystalline layer; and
a lid over the crystalline layer, wherein the lid is comprised predominantly of a metal.

12. The apparatus of claim 11, wherein the IC device layer is coupled to a power supply by the metallization structure.

13. The apparatus of claim 12, further comprising an IC die between the first dielectric section and the substrate.

14. The apparatus of claim 13, wherein the crystalline layer comprises a thermal sensor coupled to the IC device layer by a thermal pillar.

15. The apparatus of claim 14, wherein the thermal ground layer is comprised predominantly of copper, and the lid and the thermal ground layer are coupled to an apparatus electrical ground.

16. A method, comprising:
receiving a device layer and a crystalline layer; and
coupling the device layer and the crystalline layer with an array of thermal pillars therebetween by forming a hybrid bond between the device layer and the crystalline layer, wherein the thermal pillars extend through a dielectric section between the device layer and the crystalline layer, and first ends of the thermal pillars contact the device layer, and second ends of the thermal pillars contact the crystalline layer or a layer of metal between the dielectric section and the crystalline layer.

17. The method of claim 16, further comprising forming a thermal sensor in the crystalline layer.

18. The method of claim 17, wherein forming the hybrid bond thermally and electrically couples the thermal sensor to the device layer.

19. The method of claim 16, further comprising depositing a layer of metal or a dielectric material over the crystalline layer, at least some of the thermal pillars to be connected to the layer of metal or the crystalline layer.

20. The method of claim 16, further comprising forming a portion of the array of thermal pillars in a dielectric material adjacent the dielectric section or the crystalline layer.
